(19) United States
(12) Patent Application Publication
(10) Pub. No.: US 2025/0085170 A1
(43) Pub. Date: Mar. 13, 2025

(54) COMPLIANT TEMPERATURE SENSING SYSTEM

(71) Applicant: WATLOW ELECTRIC MANUFACTURING COMPANY, St. Louis, MO (US)

(72) Inventors: John LILLELAND, Morgan Hill, CA (US); Jacob LINDLEY, Nashville, TN (US)

(73) Assignee: WATLOW ELECTRIC MANUFACTURING COMPANY, St. Louis, MO (US)

(21) Appl. No.: 18/958,205

(22) Filed: Nov. 25, 2024

Related U.S. Application Data
(63) Continuation of application No. PCT/US2023/067290, filed on May 22, 2023.
(60) Provisional application No. 63/344,933, filed on May 23, 2022.

(51) Int. Cl. G01K 1/143; G01K 7/02

(52) U.S. Cl. CPC G01K 1/143; G01K 7/023

(57) ABSTRACT

A temperature sensing system to detect a temperature of a surface includes a sensor assembly and first and second lead wires. The sensor assembly includes a probe head and a temperature sensor disposed within the probe head. The first and second lead wires suspend the probe head such that the probe head abuts the surface. The first and second lead wires comprising different materials. The first and second lead wires are configured to provide multiple degrees of freedom of movement to the probe head and temperature measurements.

### CROSS-REFERENCE TO RELATED APPLICATIONS

This application is a continuation application of International Application No. PCT/US2023/067290, filed May 22, 2023, which claims priority to and the benefit of U.S. Patent Application No. 63/344,933, filed on May 23, 2022. The disclosures of the above applications are incorporated herein by reference in their entireties.

### FIELD

The present disclosure relates to temperature sensing, and more particularly to accurate temperature sensing of surfaces, or interfaces between two systems.

### BACKGROUND

The statements in this section merely provide background information related to the present disclosure and may not constitute prior art.

A variety of industrial processes use heaters in thermal applications. One such example is semiconductor processing. However, in semiconductor processing applications, temperature must be controlled within tight tolerances and the heating environment is often exposed to corrosive gases in addition to extremely high temperatures. Measuring the temperature in such challenging environments can be difficult with conventional temperature sensing devices, such as thermocouples or RTDs, primarily due to mounting requirements. Further, equipment manufacturers are reluctant to introduce additional equipment within the chamber of semiconductor processing chambers due to potential contamination and thermal disruptions.

Further, when using temperature sensors to sense temperature at a surface of a system, heat loss from the actual temperature sensor can lead to inaccurate measurements or additional calculations to compensate for the thermal impact of the temperature sensor. Mounting of known temperature sensors, whether adhesively, mechanically, or a combination of both, also contributes to inaccurate temperature measurements.

These issues related to sensing temperature of surfaces, or interfaces between two systems, while reducing the thermal impact of the actual temperature sensor are addressed by the present disclosure.

### SUMMARY

This section provides a general summary of the disclosure and is not a comprehensive disclosure of its full scope or all of its features.

In one form of the present disclosure, a temperature sensing system to detect the temperature of a surface comprises a sensor assembly. The sensor assembly includes a first lead wire and a second lead wire, wherein the first lead wire comprises a material different than a material of the second lead wire, a probe head, and a temperature sensor disposed within the probe head. The probe head is suspended by at least one of the first and second lead wires such that the probe head abuts the surface, and a flexible support is secured to a portion of at least one of the first lead wire or the second lead wire to which the probe head is suspended. The probe head is suspended away from an end of the flexible support, and the flexible support and the first and second lead wires provide multiple degrees of freedom of movement to the probe head.

In variations of this temperature sensing system, which may be implemented individually or in any combination: the probe head is substantially transparent; the probe head is supported by both the first and second lead wires; the flexible support is a leaf spring; the surface is a surface of a silicon wafer and the temperature sensor is configured to detect a temperature of the wafer surface; a material of the probe head is one of sapphire or quartz; a material of the probe head is selected from the group consisting of AlN, SiC, Si, and alumina; the first lead wire includes a platform, and the probe head is supported only by the platform; the second lead wire extends downward from the platform; the platform is cantilevered; the first and second lead wires are attached to the probe head along a common axis, and the probe head is supported only by the first and second lead wires; the flexible support includes a ceramic coating; the surface is curved and the probe head is shaped based on the curved surface; the probe head is configured to move about the multiple degrees of freedom along the curved surface.

In still another form, a computer includes a processor and a memory, the memory storing instructions executable by the processor to receive data from the temperature sensor via the first and second lead wires, the data indicating the temperature of the surface, and send the temperature data to a controller to control power to the heat source. Further, the instructions may also include: instructions to move the probe head to a different portion of the surface and to receive data from the temperature sensor at the different portion of the surface; instructions to send an instruction to cease power supply to the heat source upon receiving data from the temperature sensor indicating that the temperature of the surface exceeds a temperature threshold; and instructions to actuate a linear actuator to move the probe head along the surface.

In still another form of the present disclosure, a system for heating a target comprises a heat source directed toward a surface of the target and a temperature sensing system. The temperature sensing system comprises a sensor assembly including a first lead wire, a second lead wire, a probe head, and a temperature sensor disposed within the probe head, the probe head being suspended by at least one of the first and second lead wires such that the probe head abuts the surface, and a flexible support secured to a portion of at least one of the first lead wire or the second lead wire to which the probe head is suspended. The probe head is suspended away from an end of the flexible support, wherein the flexible support and the first and second lead wires provide multiple degrees of freedom of movement to the probe head.

In variations of this system, which may be implemented individually or in any combination: the system comprises a second temperature sensor; the system is configured to cease supplying power to the heat source upon receiving a signal from the temperature sensor indicating that a temperature of the surface of the target exceeds a threshold; the target is a silicon wafer; the system is configured to adjust power supplied to the heat source based on data from the temperature sensor or a second temperature sensor; a chamber surrounds the target and the heat source; the chamber is a semiconductor processing chamber; and the first lead wire is a different metal than a metal of the second lead wire.

In still another form of the present disclosure, a temperature sensing system to detect the temperature of a surface comprises a sensor assembly including a probe head and a temperature sensor disposed within the probe head, and first and second flexible supports suspending the probe head such that the probe head abuts the surface, the first and second flexible supports comprising different materials. The first and second flexible supports are configured to provide multiple degrees of freedom of movement to the probe head and temperature measurements.

In still another form of the present disclosure, a temperature sensing system to detect a temperature of a surface includes a sensor assembly and first and second lead wires. The sensor assembly includes a probe head and a temperature sensor disposed within the probe head. The first and second lead wires suspend the probe head such that the probe head abuts the surface. The first and second lead wires comprising different materials. The first and second lead wires are configured to provide multiple degrees of freedom of movement to the probe head and temperature measurements.

In variations of this system of the above paragraph, which may be implemented individually or in any combination: the probe head is substantially transparent; the probe head is supported by both the first and second lead wires; a flexible support secured to a portion of at least one of the first lead wire or the second lead wire and providing multiple degrees of freedom of movement to the probe head, the probe head is suspended away from an end of the flexible support; the flexible support is a leaf spring; the flexible support includes a ceramic coating; the surface is a surface of a silicon wafer and the temperature sensor is configured to detect a temperature of the wafer surface; a material of the probe head is one of sapphire or quartz; a material of the probe head is selected from the group consisting of AlN, SiC, Si, and alumina; the first lead wire includes a platform, and the probe head is supported only by the platform; the second lead wire extends downward from the platform; the platform is cantilevered; the first and second lead wires are attached to the probe head along a common axis, and the probe head is supported only by the first and second lead wires; the surface is curved and the probe head is shaped based on the curved surface; the probe head is configured to move about the multiple degrees of freedom along the curved surface; a computer including a processor and a memory, the memory storing instructions executable by the processor to: receive data from the temperature sensor via the first and second lead wires, the data indicating the temperature of the surface; and send an instruction to a power source to adjust power supplied to the heat source to adjust temperature of the heat source; the instructions further include instructions to move the probe head to a different portion of the surface and to receive data from the temperature sensor at the different portion of the surface; the instructions further include instructions to send an instruction to cease supplying power to the heat source upon receiving data from the temperature sensor indicating that the temperature of the surface exceeds a temperature threshold; the instructions further include instructions to actuate a linear actuator to move the probe head along the surface; the first lead wire is a different metal than a metal of the second lead wire; the first and second lead wires comprise first and second flexible supports, respectively, suspending the probe head such that the probe head abuts the surface, the first flexible support made of the same material as the first lead wire and the second flexible support made of the same material as the second lead wire.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a side view of an example temperature sensing system constructed in accordance with the principles of the present disclosure;

FIG. 2 is a perspective view of an example sensor assembly of the temperature sensing system of FIG. 2 and constructed in accordance with the principles of the present disclosure;

FIG. 3 is an enlarged top view of the example sensor assembly of FIG. 3;

FIG. 4 is a perspective view of another example sensor assembly constructed in accordance with the principles of the present disclosure;

FIG. 5 is a perspective cut-away view of another example sensor assembly constructed in accordance with the principles of the present disclosure;

FIG. 6 is another perspective view of the example sensor assembly of FIG. 6;

FIG. 7 is a side view of another example sensor assembly constructed in accordance with the principles of the present disclosure;

FIG. 8 is a plan view of another example sensor assembly constructed in accordance with the principles of the present disclosure;

FIG. 9 is a block diagram of an example process for operating a heat source in accordance with the principles of the present disclosure;

FIG. 10A is a plan view of another example sensor assembly constructed in accordance with the principles of the present disclosure;

FIG. 10B is a plan view of another example sensor assembly constructed in accordance with the principles of the present disclosure;

FIG. 10C is a perspective view of the example sensor assembly of FIG. 10B; and

FIGS. 11A-11F are plan views of other example sensor assemblies constructed in accordance with the principles of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

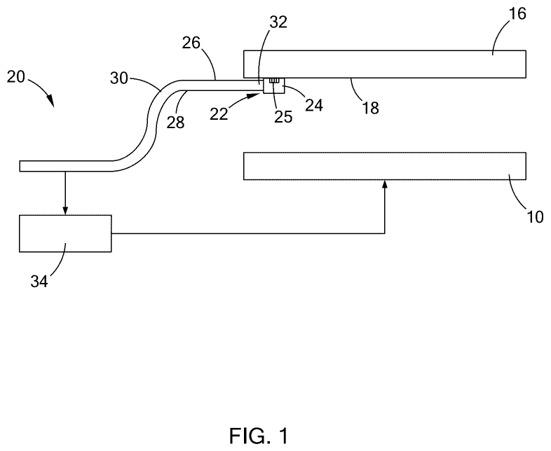

Referring to FIG. 1, an example heat source 10 provides heat to a surface 18 of an object 16. The heat source 10 in this application is used for heating objects such as silicon wafers. In one form, the heat source 10 is a resistive heating element but is not limited thereto. In other forms, the heat source 10 may include, by way of example, an inductive heating element, a visible light emitter, or a combustion heater, among others. The heat source 10 is arranged to substantially evenly heat the entire surface 18 of the object 16 facing the heat source 10. The heat source 10 is actuatable to heat the object 16 to a specified temperature, e.g., 300° C. (572° F.) and greater. It should be understood that these specific values are merely exemplary and other wattages and temperatures should be construed to be within the teachings of the present disclosure.

As further shown, a temperature sensing system 20 detects a temperature of the object 16. In order to maintain the temperature of the object 16 within a specified temperature range, data from the temperature sensing system 20 can be used to adjust output of the heat source 10, adjusting the temperature of the object 16. Maintaining the temperature of the object 16 within the specified temperature range improves manufacturing of the object 16 by reducing strains that may occur from temperature differences across the surface 18 of the object 16.

The temperature sensing system 20 includes a sensor assembly 22. The sensor assembly 22 detects the temperature of the surface 18 of the object 16. The sensor assembly 22 is movable along the surface 18 by a suitable mechanism, e.g., a linear actuator.

The sensor assembly 22 includes a probe head 24, a temperature sensor 25, a first lead wire 26, a second lead wire 28. The first and second lead wires 26, 28 are connected to the probe head 24. The probe head 24 contacts the surface 18 of the object 16, which heats the probe head 24 and the temperature sensor 25. In one form, the temperature sensor 25 is a junction of a thermocouple that detects a temperature based on a voltage difference between two wires of different materials, e.g., the lead wires 26, 28. As the temperature of the probe head 24 and the temperature sensor 25 increase, a voltage difference forms between the first lead wire 26 and the second lead wire 28, and the voltage is proportional to the temperature of the temperature sensor 25. Thus, as the voltage changes, the temperature of the temperature sensor 25 (and the surface 18 of the object 16) is detected. Alternatively, the temperature sensor 25 may be a different sensor that detects a temperature, e.g., a thermistor or a resistive temperature detector (RTD), among others.

In one variation of the present disclosure, the probe head 24 is transparent, i.e., allows light to pass through when the heat source 10 is in the form of visible light emitters (not shown). Thus the probe head 24 being a transparent material allows the surface 18 of the object 16 that would otherwise be blocked by the probe head 24 to be heated by the emitted light. Thus, the surface 18 of the object 16 is heated more evenly by the visible light transmitted through the transparent probe head 24 than a surface 18 partially blocked by an opaque or non-transparent probe head 24. The transparent material may be, by way of example, quartz or sapphire, among others. In yet another form, the probe head 24 may be another material such as aluminum nitride (AlN), silicon carbide (SIC), silicon (Si), alumina, or another ceramic material that is capable of withstanding relatively high temperatures and harsh chemical environments. It should be understood, however, that the probe head 24 may be any other material as a function of application requirements.

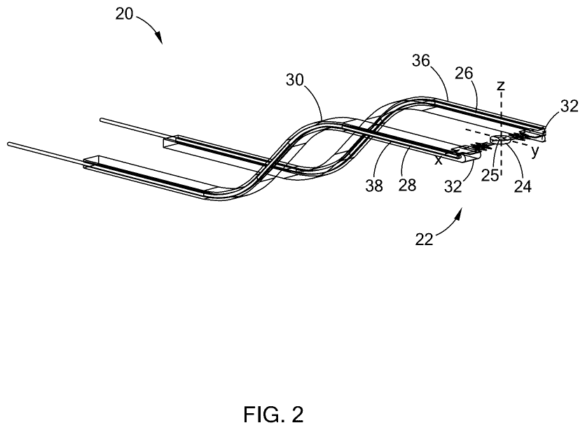

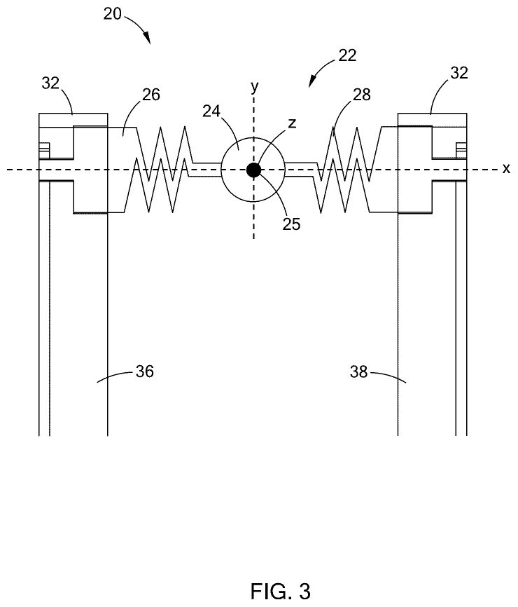

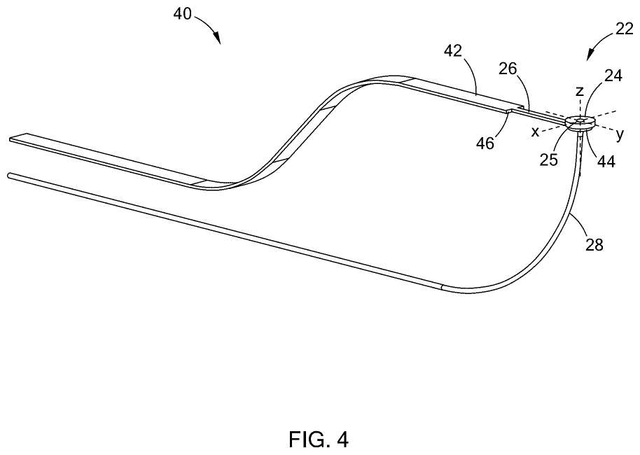

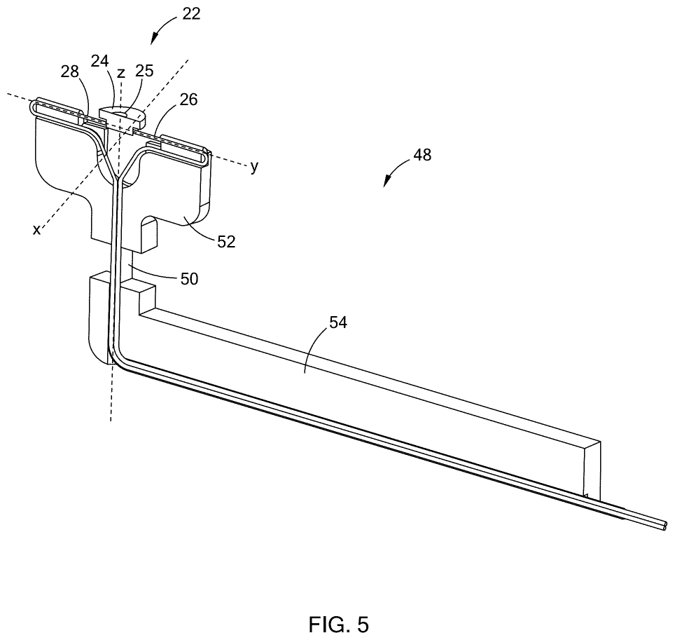

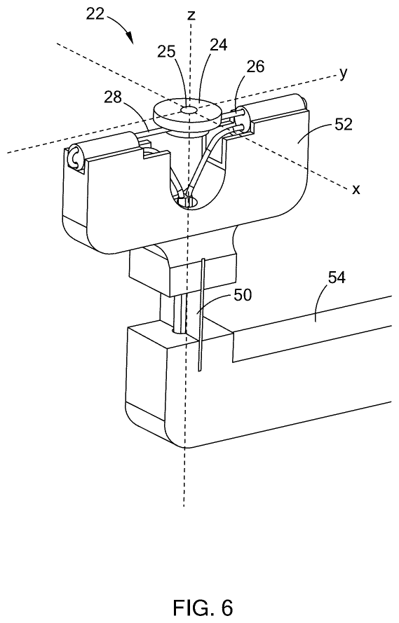

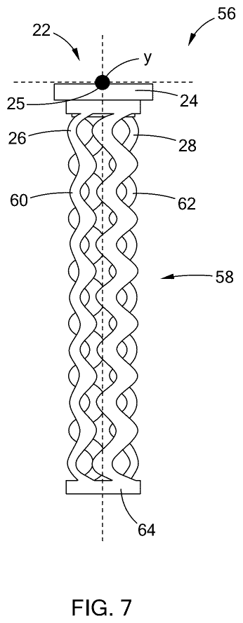

Referring to FIGS. 2 and 3, the temperature sensing system 20 includes a flexible support 30 and a base 32. The base 32 is supported by the flexible support 30. The flexible support 30 is secured to a portion of at least one of the first lead wire 26 or the second lead wire 28 to which the probe head 24 is suspended. The first and second lead wires 26, 28 extend from an end of the flexible support 30 to the probe head 24, as shown in FIGS. 2-3 in this example. Thus, the flexible support 30 and the lead wires 26, 28 provide the probe head 24 with multiple degrees of freedom of movement, including three-dimensional rotation and translation through three-dimensional space. The flexible support 30 in the example of FIGS. 2-3 is a pair of arms, in the example of FIG. 4 is a cantilevered platform, in the example of FIGS. 5-6 is a leaf spring, and in the example of FIG. 7 is a pair of coiled springs.

According to one form of the present disclosure, the flexible supports as illustrated and described herein comprise different materials, similar to the lead wires 26, 28, such that the temperature can be detected through the use of different materials for the flexible supports rather than, or in addition to, the lead wires 26, 28. In some variations of the present disclosure, the lead wires 26, 28 may also be construed to be supports in and of themselves.

As further shown in FIG. 1, a controller 34 provides instructions to the heat source 10 based on data received from the temperature sensor 25. The controller 34 is a computer including a processor and a memory. The memory stores instructions executable by the processor. The controller 34 receives the data indicating the change in the voltage between the first and second lead wires 26, 28 indicating the temperature of the temperature sensor 25, i.e., the “temperature data.” The controller 34 thus controls operation of the heat source 10, via a power source (not shown) to heat the object 16 to a specified temperature.

The controller 34 is configured to control output of the heat source 10 upon receiving temperature data from the temperature sensor 25. When the temperature of the object 16 exceeds a temperature threshold, the controller 34 can instruct the power source to reduce output of the heat source 10, thus reducing an amount of heat transferred to the object 16. When the temperature of the object 16 is below a second temperature threshold, the controller 34 can send instructions to the power source to increase output of the heat source 10, increasing the amount of heat transferred to the object 16. The thresholds are determined based on, e.g., temperature data from empirical testing of heat source 10 emitting specified amounts of heat onto test objects 16.

With references to FIGS. 2-3, the flexible support 30 of the sensor assembly 22 includes a first arm 36 and a second arm 38, each arm housing one of the lead wires 26, 28. The first arm 36 houses the first lead wire 26, and the second arm 38 houses the second lead wire 28. Each arm 36, 38 is movable relative to the other arm 36, 38, independently moving, e.g., by a linear actuator, and the lead wires 26, 28 move with their respective arms 36, 38. The base 32 is disposed at respective ends of the arms 36, 38, and the lead wires 26, 28 extend from the base 32.

The probe head 24 of the sensor assembly 22 is suspended by the first and second lead wires 26, 28 between the arms 36, 38. In this form, the first and second lead wires 26, 28 are directly attached to the probe head 24 and support the weight of the probe head 24 from the base 32 between the arms 36, 38. Because the probe head 24 is supported solely by the lead wires 26, 28 away from the base 32, the probe head 24 is rotatable about two axes of rotation, axes x, y. In this context, the letters x, y, z refer to orthogonal axes in a three-dimensional coordinate system, such as a rectangular Cartesian coordinate system. The lead wires 26, 28 do not substantially resist rotation of the probe head 24, and the probe head 24 rotates according to a surface contour of the object 16. The probe head 24 rotates about the x axis that extends along the lengths of the first and second lead wires 26, 28, which do not resist rotation thereabout. The probe head 24 rotates about the y axis that is perpendicular to the lead wires 26, 28 because the lead wires 26, 28 are flexible, and as the contour of the surface of the object 16 pushes one side of the probe head 24 downward, the respective lead wire 26, 28 attached to the one side moves with the probe head 24, rotating the probe head 24 about the y axis. Thus, the probe head 24 maintains contact with the surface 18 of the object 16 so that the temperature sensor 25 detects the temperature of the surface 18 and transmits temperature data to the controller 34.

Because the arms 36, 38 of the flexible support 30 move independently of each other, the probe head 24 is rotatable about the z axis, a vertical axis normal to the x, y axes and is translatable throughout the three-dimensional coordinate system. In this example, as the first arm 36 moves in a forward-rearward direction relative to the second arm 38, the lead wires 26, 28 rotate the probe head 24 about the z axis. The arms 36, 38 position the probe head 24 to a specified location on the surface 18 of the object 16, the probe head 24 is movable about these multiple degrees of freedom to maintain contact with the surface 18 of the object 16. Thus, the temperature sensor 25 detects the temperature of the object 16 according to the geometry of the surface 18 of the object 16.

With reference to FIG. 4, a sensor assembly 40 includes a flexible support 42. The flexible support 42 of the sensor assembly 40 includes a cantilevered platform 44. The platform 44 extends from the first lead wire 26 and is a same material as the first lead wire 26. As such, the platform 44 generates a voltage as the first metal of the thermocouple junction. The second lead wire 28 extends downward from the platform 44. The platform 44 is spaced from a base 46, and the first lead wire 26 extends from the base 46 to the platform 44. The platform 44 is cantilevered, i.e., free to bend relative to the base 46. The probe head 24 is supported by the platform 44. The platform 44 urges the probe head 24 and the temperature sensor 25 against the surface 18 of the object 16.

The platform 44 provides the probe head 24 with multiple degrees of freedom to rotate about the three axes of rotation according to the geometry of the surface 18 of the object 16 and to translate along the surface 18. The probe head 24 rotates about the x axis because the lead wires 26, 28 do not resist rotation thereabout and the platform 44 is cantilevered, flexibly allowing the probe head 24 to rotate. The probe head 24 rotates about the y axis because the lead wires 26, 28 are flexible and do not resist rotation thereabout. The probe head 24 rotates about the z axis because the platform 44 and the first lead wire 26 are flexible about the z axis, and the second lead wire 28 is attached beneath the probe head 24 in the direction of the z axis and does not resist rotation thereabout.

With reference to FIGS. 5-6, a flexible support 50 of a sensor assembly 48 in one form is a leaf spring 50. More specifically, the leaf spring 50 comprises a plurality of layers of flexible bands (not shown) and could include additional bands depending on the desired displacement of the sensor assembly 48. The leaf spring 50 connects a base 52 to an arm 54 of the sensor assembly 48. The arm 54 is translatable by a suitable mechanism, e.g., a linear actuator. The leaf spring 50 is rotatable about the x axis. The base 52 is disposed on the leaf spring 50, and the base 52 allows the probe head 24 to rotate about the x axis. As the arm 54 moves the base 52 along the surface 18 of the object 16, the base 52 causes the leaf spring 50 to flex, rotating the base 52 relative to the arm 54.

The first and second lead wires 26, 28 extend from the arm 54 along the leaf spring 50 and up along the base 52 to the probe head 24. The probe head 24 is suspended by the first and second lead wires 26, 28 away from the base 52 and is rotatable about the y, z axes. That is, the lead wires 26, 28 do not resist rotation of the probe head 24 along the y, z axes and may resist rotation of the probe head 24 along the x axis. As the base 52 rotates with the leaf spring 50, the probe head 24 rotates about the x axis. Thus, the leaf spring 50 and the lead wires 26, 28 allow the probe head 24 to rotate about the three axes of rotation x, y, z according to the geometry of the surface 18 of the object 16 so that the temperature sensor 25 collects temperature data from the object 16.

With reference to FIG. 7, a flexible support 58 of a temperature sensor assembly system 56 includes a first coiled spring 60 and a second coiled spring 62. The first and second coiled springs extend from a base 64. The base 64 is translatable by a suitable mechanism, e.g., a linear actuator. The first coiled spring 60 includes the first lead wire 26, i.e., the first coiled spring 60 is the first part of the thermocouple circuit. The second coiled spring 62 includes the second lead wire 28, i.e., the second coiled spring 62 is the second part of the thermocouple circuit. Thus, the first and second coiled springs 60, 62 generate temperature data collectable by the temperature sensor 25 for the controller.

The probe head 24 is supported by the first and second coiled springs 60, 62. The first and second coiled springs 60, 62 urge the probe head 24 from the base 64 onto the surface 18 of the object 16. In this form, the first and second coiled springs 60, 62 are each flexible, and as the probe head 24 moves against the surface 18 of the object 16, the first and second coiled springs 60, 62 contract and expand to maintain contact between the probe head 24 and the surface 18. Because the first and second coiled springs 60, 62 do not substantially resist movement about any of the x, y, z axes, as the first and second coiled spring 60, 62 urge the probe head, 24 the probe head 24 moves to align with the contours of the surface 18 of the object 16. That is, the coiled springs 60, 62 flex relative to the base 64 when the object 16 pushes on the probe head 24, providing the probe head 24 multiple degrees of freedom to align with the geometry of the surface 18 of the object 16. As the coiled springs 60, 62 flex, the probe head 24 translates and rotates freely in three-dimensional space.

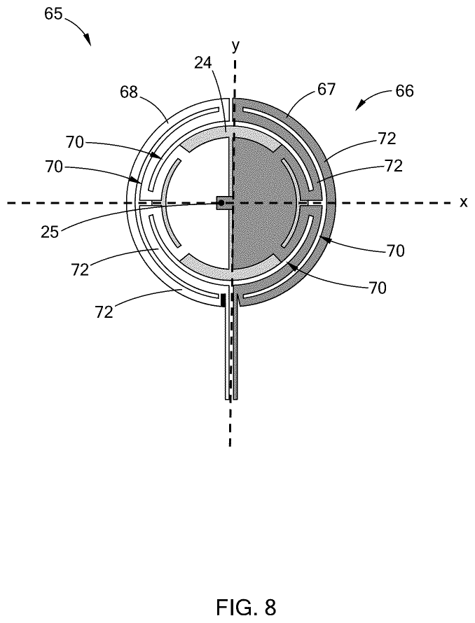

With reference to FIG. 8, another form of a temperature sensor assembly of the present disclosure is illustrated and indicated by reference numeral 65. The temperature sensor assembly 65 includes a flexible support 66, which supports the probe head 24 and the temperature sensor 25 (in this form, a thermocouple junction). The flexible support 66 includes a first flexible support 67 (i.e., the electrical equivalent of the previously described first lead wire 26), and a second flexible support 68 (i.e., the electrical equivalent of the previously described second lead wire 28), wherein the first and second flexible supports 67, 68 are arranged to flexibly support the probe head 24 about the X and Y axes and along the Z-axis. More specifically, the first and second flexible supports 67, 68 include a plurality of slots or openings 70 extending through the first and second flexible supports 67, 68 to form a plurality of undulating arms 72. The openings 70 and undulating arms 72 combine to allow the flexible support 66 to be displaced along the Z-axis, and rotated about the X and Y axes, with lower forces, thereby providing the desired “flexibility” or displacement in operation, as compared with a solid support (not shown). Similar to the variations set forth above, the flexible support 66 provides multiple degrees of freedom of movement, including three-dimensional rotation and translation through three-dimensional space. Accordingly, the first and second flexible supports 67, 68 provide a dual function of both mechanical flexibility and electrical leads to form a temperature sensor.

The first flexible support in this form is an alumel foil, and the second flexible support in this form is a chromel foil. The alumel and chromel foils form a thermocouple junction on the probe head 24, thus forming the temperature sensor 25. The flexible supports 67, 68 are formed in concentric half or quarter circles to allow the probe head 24 to move along the z axis. In another form not shown in FIG. 8, the probe head is omitted, and the flexible supports 67, 68 directly support the temperature sensor 25. It should be understood that alumel and chromel are only example materials to form a thermocouple and other thermocouple materials may be employed while remaining within the scope of the present disclosure.

Accordingly, the present disclosure provides innovative temperature measurement systems for more accurately sensing the temperature of a surface, which as used herein is the interface between two systems. The temperature measurement system of the present disclosure, or surface sensor, creates a new system at that location and interface. The measured temperature is a value within this new system and can be engineered to represent more accurately a particular location of a substrate being measured. By artificially extending the bulk of the substrate (flexible support) it is possible to obtain a temperature that is closer to the bulk of the target substrate as opposed to the surface interface temperature.

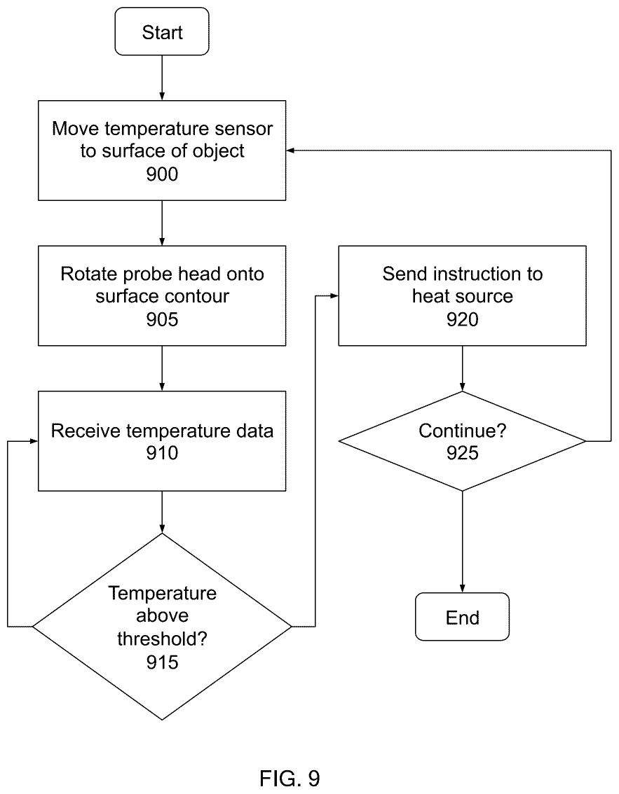

Referring now to FIG. 9, an example process for heating an object 16 with a heat source 10 is illustrated. The process begins in a block 900, in which a controller 34 instructs a linear actuator to move a sensor assembly 22 to a surface 18 of an object 16. As described above, the sensor assembly 22 collects temperature data from a specified location on the surface 18 of the object 16.

Next, in a block 905, the controller 34 moves a probe head 24 of the sensor assembly 22 to a contour of the surface 18. As described above, the probe head 24 is provided multiple degrees of freedom to translate and rotate along the geometry of the surface 18. For example, the probe head 24 is supported by a flexible support 30 and by first and second lead wires 26, 28, each of the flexible support 30 and the first and second lead wires 26, 28 rotating the probe head 24 according to the contour of the surface 18. Because the probe head 24 is suspended by the lead wires 26, 28, the probe head 24 can rotate along axes x, y, z of rotation.

Next, in a block 910, the controller 34 receives temperature data from a temperature sensor 25 supported by the probe head 24. As described above, the first and second lead wires 26, 28 form a thermocouple junction at the temperature sensor 25, and a change in the voltage difference between the first and second lead wires 26, 28 is proportional to a temperature of the temperature sensor 25, and by extension, the temperature of the surface 18 of the object 16. The controller 34 can, based on the temperature data and the materials of the first and second lead wires 26, 28, determine the temperature of the object 16.

Next, in a block 915, the controller 34 determines whether the temperature data indicate that the temperature of the surface 18 of the object 16 exceeds a predetermined threshold. The predetermined threshold is a value stored in a memory of the controller 34. The threshold is a specified temperature beyond which the heat source 10 should not heat the object 16. If the temperature exceeds the threshold, the process continues in a block 920. Otherwise, the process returns to the block 910.

In the block 920, the controller 34 sends an instruction to the heat source 10 to adjust operation of heat source 10 based on the temperature data. For example, the controller 34 can send an instruction to reduce output from the heat source 10 to reduce heating of the object 16. In another example, the controller 34 can cease actuation of the heat source 10 to cease heating the object 16.

Next, in a block 925, the controller 34 determines whether to continue the process. For example, the controller 34 can determine to continue the process upon determining to move the probe head 24 to a different portion of the object 16. If the controller 34 determines to continue, the process returns to the block 900. Otherwise, the process ends.

The probe head 24 in the embodiments described includes the temperature sensor 25, i.e., a sensor designed to collect temperature data. Alternatively or additionally, other sensors are supported by the probe head 24 to collect data from the object 16. For example, the sensor can be a vibration sensor, an optical sensor, or a chemical sensor. The sensors transmit respective data to the controller 34, which operates one or more components based on the data.

Referring now to FIGS. 10A-10C, additional forms of the present disclosure include a sensor assembly 74 with a first leg 76, a second leg 78, and a third leg 80. The legs 76, 78, 80 meet at a probe head 82. Two of the three legs 76, 78, 80 are different materials, similar to those described above, such that the probe head 82 forms a thermocouple junction. The legs 76, 78, 80 are fixed to a base 84 that is movable to the object 16. The legs 76, 78, 80 are flexible to move the probe head 82 away from the base 84 and toward the surface 18 of the object 16. Because two of the legs 76, 78, 80 form the thermocouple junction, the probe head 82 provides temperature data to the controller 34 to control the heat source 10. As shown in FIG. 10C, the legs 76, 78, 80 extend the probe head 82 downward away from the base 84. In another form, the sensor assembly 74 includes a different number of legs, such as two or four.

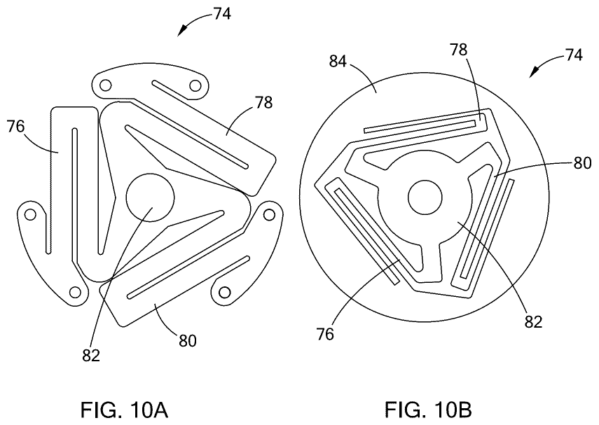

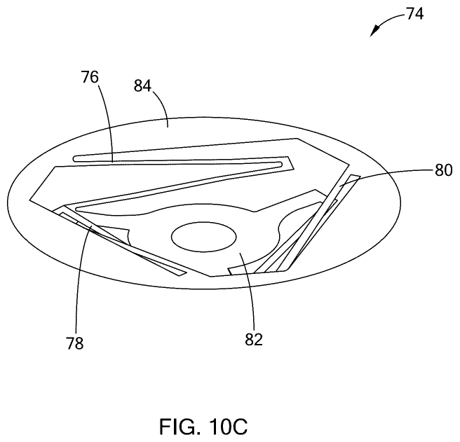

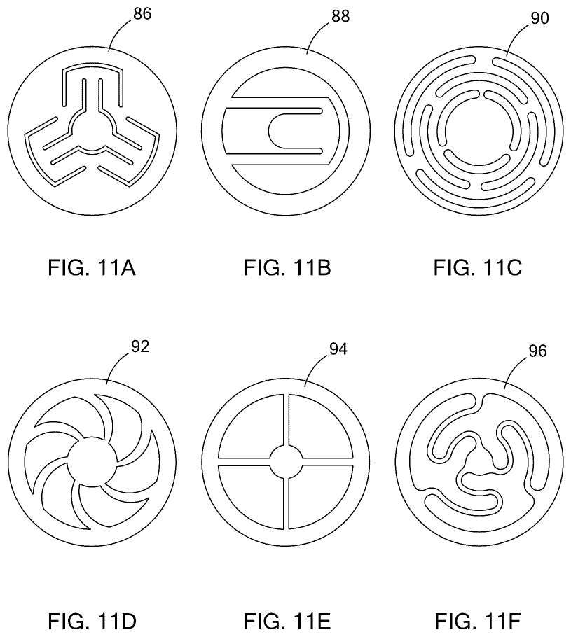

Referring now to FIGS. 11A-11F, different forms of sensor assemblies 86, 88, 90, 92, 94, 96 are shown to collect temperature data from the surface 18 of the object 16. Each of the assemblies is flexible to allow the thermocouple junction to follow the contour of the surface 18. In the form of FIG. 11A, the sensor assembly 86 includes grooves machined in a triangular pattern to allow a center portion including the thermocouple junction to flex away from an outer portion, holding the thermocouple junction against the contour of the surface 18. In the form of FIG. 11B, the sensor assembly 88 includes a ledge extending from an outer portion, the ledge supporting the thermocouple junction and flexible relative to the outer portion to hold the thermocouple junction against the contour of the surface 18. In the form of FIG. 11C, the sensor assembly 90 includes a plurality of arcuate grooves that allow a center portion supporting the thermocouple junction to flex away from an outer portion, holding the thermocouple junction against the contour of the surface 18. In the form of FIG. 11D, the sensor assembly 92 includes a plurality of arcuate legs extending from an outer portion to support a center portion supporting the thermocouple junction, allowing the center portion to flex away from the outer portion to hold the thermocouple junction against the contour of the surface 18. In the form of FIG. 11E, the sensor assembly 94 a plurality of straight legs extending from an outer portion to support a center portion supporting the thermocouple junction, allowing the center portion to flex away from the outer portion to hold the thermocouple junction against the contour of the surface 18. In the form of FIG. 11F, the sensor assembly 96 includes a plurality of anfractuous (i.e., sinusoidal or serpentine) legs extending from an outer portion to support a center portion supporting the thermocouple junction, allowing the center portion to flex away from the outer portion to hold the thermocouple junction against the contour of the surface 18. The shapes of the sensor assemblies 86, 88, 90, 92, 94, 96 provide multiple degrees of freedom such that the thermocouple junction collects temperature data along the entire surface 18 of the object 16.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

In this application, the term “controller” and/or “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components (e.g., op amp circuit integrator as part of the heat flux data module) that provide the described functionality; or a combination of some or all of the above, such as in a system-on-chip.

The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A temperature sensing system to detect a temperature of a surface, the temperature sensing system comprising:
a sensor assembly including a probe head and a temperature sensor disposed within the probe head; and
first and second lead wires, at least one of the first and second lead wires suspending the probe head such that the probe head abuts the surface, the first and second lead wires comprising different materials,
wherein the first and second lead wires are configured to provide multiple degrees of freedom of movement to the probe head and temperature measurements.

2. The temperature sensing system of claim 1, wherein the probe head is substantially transparent.

3. The temperature sensing system of claim 1, wherein the probe head is supported by both the first and second lead wires.

4. The temperature sensing system of claim 1, further comprising a flexible support secured to a portion of at least one of the first lead wire or the second lead wire and providing multiple degrees of freedom of movement to the probe head, the probe head is suspended away from an end of the flexible support.

5. The temperature sensing system of claim 4, wherein the flexible support is a leaf spring.

6. The temperature sensing system of claim 4, wherein the flexible support includes a ceramic coating.

7. The temperature sensing system of claim 1, wherein the surface is a surface of a silicon wafer and the temperature sensor is configured to detect a temperature of the wafer surface.

8. The temperature sensing system of claim 1, wherein a material of the probe head is one of sapphire or quartz.

9. The temperature sensing system of claim 1, wherein a material of the probe head is selected from the group consisting of AlN, SiC, Si, and alumina.

10. The temperature sensing system of claim 1, wherein the first lead wire includes a platform, and the probe head is supported only by the platform.

11. The temperature sensing system of claim 10, wherein the second lead wire extends downward from the platform.

12. The temperature sensing system of claim 10, wherein the platform is cantilevered.

13. The temperature sensing system of claim 1, wherein the first and second lead wires are attached to the probe head along a common axis, and the probe head is supported only by the first and second lead wires.

14. The temperature sensing system of claim 1, wherein the surface is curved and the probe head is shaped based on the curved surface.

15. The temperature sensing system of claim 14, wherein the probe head is configured to move about the multiple degrees of freedom along the curved surface.

16. The temperature sensing system of claim 1, further comprising a computer including a processor and a memory, the memory storing instructions executable by the processor to:
receive data from the temperature sensor via the first and second lead wires, the data indicating the temperature of the surface; and
send an instruction to a power source to adjust power supplied to a heat source to adjust temperature of the heat source.

17. The temperature sensing system of claim 16, wherein the instructions further include instructions to move the probe head to a different portion of the surface and to receive data from the temperature sensor at the different portion of the surface.

18. The temperature sensing system of claim 16, wherein the instructions further include instructions to send an instruction to cease supplying power to the heat source upon receiving data from the temperature sensor indicating that the temperature of the surface exceeds a temperature threshold.

19. The temperature sensing system of claim 16, wherein the instructions further include instructions to actuate a linear actuator to move the probe head along the surface.

20. The temperature sensing system of claim 1, wherein the first lead wire is a different metal than a metal of the second lead wire.

21. The temperature sensing system of claim 1, wherein the first and second lead wires comprise first and second flexible supports, respectively, suspending the probe head such that the probe head abuts the surface, the first flexible support made of the same material as the first lead wire and the second flexible support made of the same material as the second lead wire.
